(19) United States
(12) Patent Application Publication
(10) Pub. No.: US 2006/0157774 A1
(43) Pub. Date: Jul. 20, 2006

(54) MEMORY CELL

(76) Inventor: Kent Kuohua Chang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,378

(22) Filed: May 10, 2005

(30) Foreign Application Priority Data
Jan. 20, 2005 (TW) 94101630

(51) Int. Cl. H01L 29/788

(52) U.S. Cl. 257/315

(57) ABSTRACT

A memory cell is provided as including a substrate, a tunneling dielectric layer, a charge trapping layer, an inter-gate dielectric layer, a metal gate layer, and a source/drain region. The source/drain region is formed in the substrate besides the gate structure that includes the tunneling dielectric layer, charge trapping layer, inter-gate dielectric layer, and metal gate layer. The tunneling dielectric layer is formed on the substrate, the charge trapping layer is formed on the tunneling dielectric layer, the inter-gate dielectric layer is formed on the charge trapping layer, and the metal gate layer is formed on the inter-gate dielectric layer.

### CROSS-REFERENCE TO RELATED APPLICATION

This application claims the priority benefit of Taiwan application serial no. 94101630, filed on Jan. 20, 2005. All disclosure of the Taiwan application is incorporated herein by reference.

### BACKGROUND OF THE INVENTION

1. Field of the Invention

The present invention relates to a semiconductor device, and more particularly to a memory cell.

2. Description of the Related Art

Nonvolatile memory is used today on different electronic devices for purposes of, such as, storing structural data, programming data and other types of data suitable for repeated operations of writing and read. Electrically erasable programmable read only memory (EEPROM) is a type of nonvolatile memory that allows multiple operations of data writing, read and erasing and, furthermore, the data stored therein will not be vanished even after power supply for the memory is cut off. EEPROM hence has been widely used on personal computers and other electronic devices.

Silicon nitride read only memory is a type of conventional nonvolatile memory currently used in industry. As shown in FIG. 1, a silicon nitride read only memory consists of a substrate 100, a gate structure 111, a source/drain region 102, and an insulator 113. Wherein, the gate structure 111 is formed on the substrate 100, whereas the gate structure 111 contains, starting sequentially from the substrate, a tunneling oxide layer 101 (silicon oxide), a charge trapping layer 103 (silicon nitride), an inter-gate dielectric layer 105 silicon oxide) and a gate 107 (doped polysilicon), which forms a structure of silicon/silicon oxide/silicon nitride/silicon oxide/silicon (SONOS).

In the foregoing conventional memory cell, it is necessary to reduce the thickness of the tunneling oxide layer to allow hot electrons to easily pass through the tunneling oxide layer, enter and be trapped in the charge trapping layer. There exist, however, certain difficulties to fabricate a thin tunneling oxide layer. During a process of fabricating a thin tunneling oxide layer, for example, it is difficult to control the uniformity of the thickness and to lower density of defects. Furthermore, if the tunneling oxide layer is too thin, electric leakage will often occur, which may lower efficiency of data storing processes and reliability of the memory cell.

In addition, in the foregoing conventional memory cell structures, the gate 107 is made of doped polysilicon, whereas the inter-gate dielectric layer is made of silicon oxide. The use of the foregoing two types of materials in combination will usually cause gate depletion, and, as a result, a barrier will be formed on the interface of the two materials to adversely affect current transfer. Moreover, boron ions doped in the polysilicon will diffuse along the edges of polysilicon grains and further penetrate the inter-gate dielectric layer to cause so-called boron penetration effect. Such boron penetration effect will affect doping concentration in the channels, and further, change the threshold voltage of the memory cell. As a result, stability and reliability the memory cell will be lowered.

Furthermore, in an etching process for forming the insulator 113 of the foregoing conventional memory cell, the silicon channel will be easily eroded because of similar etching selectivity of the ONO structure and the insulator. Consequently, reliability of the memory cell will also be lowered.

### SUMMARY OF THE INVENTION

In view of the above, the present invention is directed to provide a memory cell suitable of solving the problems of electricity leakage, increasing the integration of the memory cell, and increasing the efficiency of programming/erasing operations of the memory cell.

The present invention is also directed to provide a memory cell suitable of enhancing quality of the inter-gate dielectric layer, increasing gate coupling rate of the memory cell, so as to lower the operation voltage, and increase the efficiency, stability and reliability of the memory cell.

According to an embodiment of the present invention, the present invention provides a memory cell including a substrate, a gate structure, and a source/drain region. The gate structure, as formed on the substrate, contains a tunneling dielectric layer, a charge trapping layer, an inter-gate dielectric layer, and a metal gate layer. The tunneling dielectric layer is formed on the substrate and is made of, for example, aluminum-hafnium oxide. The charge trapping layer is formed on the tunneling dielectric layer, the inter-gate dielectric layer is form on the charge trapping layer, and the metal layer is formed on the inter-gate dielectric layer. In addition, the source/drain region is formed in the substrate besides the gate structure.

According to embodiments of the above memory cell of the present invention, the gate structure contains a conductive layer that is formed on the metal gate layer and is made of, for example, metal germanium silicide. The metal gate layer is made of, for example, tantalum silicon nitride. The memory cell can further include a silicide layer, which is disposed on the metal gate layer as well as the source/drain region, and is made of, for example, germanium-nickel silicide. The charge trapping layer is made of, for example, silicon nitride. The memory cell can also further include an insulator that is disposed on the sidewalls of the gate structure.

The present invention provides another type of memory cell including a substrate, a gate structure and a source/drain region. Wherein, the gate structure is formed in the substrate and contains a tunneling dielectric layer, a charge trapping layer, an inter-gate dielectric layer, and a metal gate layer. The tunneling dielectric layer is formed on the substrate and has a dielectric constant of over 4. In addition, the charge trapping layer is formed on the tunneling dielectric layer. Further, the inter-gate dielectric layer is formed on the charge trapping layer and is made of, for example, aluminum silicide, whereas, the metal gate layer is formed on the inter-gate dielectric layer, and the source/drain region is formed in the substrate besides the gate structure.

According to embodiments of the above memory cell of the present invention, the gate structure contains a conductive layer, which is formed on the metal gate layer and is made of, for example, tantalum silicon nitride. The memory cell can further include a silicide layer, which is disposed above the metal gate layer and the source/drain region and is made of silicon germanium-nickel silicide, for example. The charge trapping layer is made of, for example, silicon nitride. The memory cell can also further include an insulator that is disposed on the sidewalls of the gate structure. The tunneling dielectric layer is made of, for example, aluminum-hafnium oxide, the metal gate layer is made of, for example, tantalum silicon nitride, and the gate structure contains a conductive layer, which is formed on the metal gate layer and is made of metal germanium silicide, for example. The memory cell can also further include a silicide layer that is formed above the source/drain region.

In the present invention, materials with high dielectric constants, such as aluminum-hafnium oxide, are used for fabricating the tunneling dielectric layer. These materials are suitable to form thin films with uniform thickness and good interface properties. These materials also have high thermal stability, and can be used to fabricate integrated circuits with higher integration. Thus, the use of such materials with high dielectric constants can reduce the chance of electricity leakage, and increase the efficiency of programming/erasing operations.

In addition, other materials, such as aluminum oxide, are used for forming the inter-gate dielectric layer to improve the quality of the inter-gate dielectric layer, increase gate-coupling efficiency of the memory cell, lower operating voltage, and further, increase efficiency of the memory cell.

Furthermore, the materials used for fabricating the charge trapping layer, the inter-gate dielectric layer and the metal gate layer have high etching selectivity with respect to the insulator, so as to avoid problems of silicon channel erosion during an etching process for the insulator.

It is to be understood that both the foregoing general description and the following detailed description are exemplary, and are intended to provide further explanation of the invention as claimed.

### BRIEF DESCRIPTION OF THE DRAWINGS

FIG. 1 is a sectional view showing a conventional memory cell.

FIG. 2 is a sectional view showing a memory cell according to a preferred embodiment of the present invention.

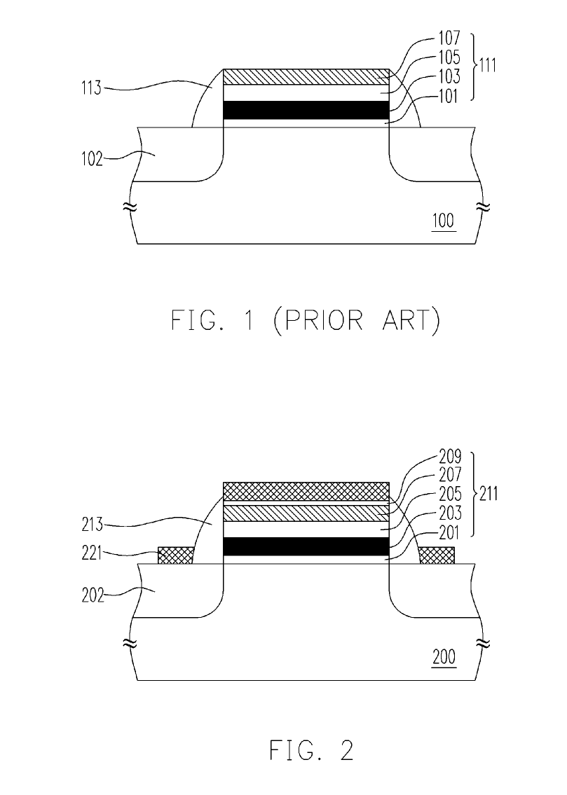

### DESCRIPTION OF THE PREFERRED EMBODIMENTS

FIG. 2 shows schematically a structure of a memory cell according to a preferred embodiment of the present invention. As shown in FIG. 2, the memory cell of this invention includes a substrate 200, a gate structure 211, and a source/drain region 202. Wherein, the gate structure 211 is formed on the substrate and the source/drain region 202 is formed in the substrate 200 besides the gate structure 211.

The gate structure 211 contains, stacking sequentially from the bottom, a tunneling dielectric layer 201, a charge trapping layer 203, an inter-gate dielectric layer 205, and a metal gate layer 207. The tunneling dielectric layer 201 is formed on the substrate 100, the charge trapping layer 203 is formed on the tunneling dielectric layer 201, the inter-gate dielectric layer 205 is form on the charge trapping layer 203, and the metal layer 207 is formed on the inter-gate dielectric layer 205.

Wherein, the tunneling dielectric layer 201 is made of, for example, aluminum-hafnium oxide, or a material with dielectric constant greater than 4, or other appropriate materials. When these types of materials are used, the tunneling dielectric layer 201 formed therefrom has uniform thickness, good interface properties, and high thermal stability; all of which are desirable for fabricating integrated circuits with higher integration. In addition, the use of such materials with high dielectric constants to fabricate the tunneling dielectric layer 201 can also reduce the chance of electricity leakage, and increase the efficiency of programming/erasing operations.

In addition, the charge trapping layer 203 is made of, for example, silicon nitride, the inter-gate dielectric layer 205 is made of, for example, aluminum oxide, and the metal gate layer 207 is made of, for example, tantalum silicon nitride.

Wherein, the use of aluminum oxide for forming the inter-gate dielectric layer 203 can improve the quality of the inter-gate dielectric layer, increase gate-coupling efficiency of the memory cell, lower operating voltage, and further, increase efficiency of the memory cell.

Furthermore, the use of the metal gate layer 207 in place of a conventional polysilicon gate can avoid such problems as gate depletion and boron penetration occurring in a doping process of polysilicon. Thus, gate conducting capacity can be increased, stability and reliability of the memory cell can be enhanced, and the thickness of the gate can be reduced; all of which are desirable for increasing integration of the memory cell.

In this embodiment, the gate structure 211 contains a conductive layer 209, which is formed on the metal gate layer 207 and is made of, for example, metal germanium silicide. Metal germanium silicide is formed through, for example, a process of silicon germanium reacts with nickel to form metal silicide. In this embodiment, the conductive layer 209 is described here as being contained in the gate structure 211; however, the conductive layer 209 is optional depending on the actual needs.

In this embodiment, the memory cell can further include a silicide layer 221, which is disposed on the metal gate layer 207 as well as the source/drain region 202, and is made of, for example, metal germanium silicide. The silicide layer 221 is formed through, for example, a process of forming self-aligned silicide. Prior to the process of forming self-aligned silicide, as shown in FIG. 2, a silicon germanium is formed on the substrate 200. This process differs from that of forming a self-aligned silicide directly on an electrode. The silicide layer 221 protrudes from the metal gate layer 207 and the source/drain region 202. In this embodiment, the suicide layer 221 is described here as being contained in the memory cell; however, the silicide layer 221 is optional depending on the actual needs.

In this embodiment, the memory cell can further include an insulator 213, which is disposed on the sidewalls of the gate structure 211, and is made of, for example, silicon oxide. Here, the materials used for fabricating the charge trapping layer 203, the inter-gate dielectric layer 205 and the metal gate layer 207 have high etching selectivity with respect to the insulator, so that the problem of silicon channel erosion during an etching process for the insulator 213 can be avoided.

Based on the foregoing, the present invention employs materials with high dielectric constants, such as aluminum-hafnium oxide, for fabricating the tunneling dielectric layer of the memory cell. The films formed from these materials has uniform thickness, good interface properties, and high thermal stability; all of which are desirable for fabricating integrated circuits with higher integration. In addition, the use of such materials with high dielectric constants can also reduce the chance of electricity leakage, and increase the efficiency of programming/erasing operations.

In addition, the use of the other materials such as aluminum oxide for forming the inter-gate dielectric layer can improve the quality of the inter-gate dielectric layer, increase gate-coupling efficiency of the memory cell, lower operating voltage, and further, increase efficiency of the memory cell. Besides, the use of the metal gate layer in place of a conventional polysilicon gate can avoid such problems as gate depletion and boron penetration, and can increase the gate conducting capacity and enhance the stability and reliability of the memory cell. Further, the use of metal for the gate layer can reduce the thickness of the gate layer, which is desirable for increase the integration of the memory cell.

Furthermore, the materials used in this invention for fabricating the charge trapping layer, the inter-gate dielectric layer and the metal gate layer have high etching selectivity with respect to the insulator, so that the problem of silicon channel erosion during an etching process for the insulator can be avoided.

It will be apparent to those skilled in the art that various modifications and variations can be made to the embodiments of the present invention without departing from the scope or spirit of the invention. In view of the foregoing, it is intended that the present invention covers modifications and variations of this invention provided they fall within the scope of the following claims and their equivalents.

What is claimed is:

1. A memory cell comprising:
a substrate;
a tunneling dielectric layer, disposed on the substrate, the tunneling dielectric layer being made of aluminum-hafnium oxide;
a charge trapping layer disposed on the tunneling dielectric layer;
an inter-gate dielectric layer disposed on the charge trapping layer;
a metal gate layer disposed on the inter-gate dielectric layer.

2. The memory cell according to claim 1, further comprising a conductive layer disposed on the metal gate layer.

3. The memory cell according to claim 2, wherein the conductive layer is made of metal germanium silicide.

4. The memory cell according to claim 1, wherein the metal gate layer is made of tantalum silicon nitride.

5. The memory cell according to claim 1, wherein the charge trapping layer is made of silicon nitride.

6. The memory cell according to claim 1, wherein the tunneling dielectric layer, the charge trapping layer, the inter-gate dielectric layer, and the metal gate layer form a gate structure.

7. The memory cell according to claim 6, further comprising a source/drain region, disposed in the substrate at each side of the gate structure.

8. The memory cell according to claim 7, further comprising a silicide layer disposed on the metal gate layer and the source/drain region.

9. The memory cell according to claim 8, wherein the silicide layer is made of silicon germanium-nickel silicide.

10. The memory cell according to claim 6, further comprising a spacer on a sidewall of the gate structure.

11. A memory cell comprising:
a substrate;
a tunneling dielectric layer, disposed on the substrate, the tunneling dielectric layer having a dielectric constant greater than 4;
a charge trapping layer disposed on the tunneling dielectric layer;
an inter-gate dielectric layer disposed on the charge trapping layer and being made of aluminum oxide;
a metal gate layer disposed on the inter-gate dielectric layer.

12. The memory cell according to claim 11, further comprising a conductive layer, disposed on the metal gate layer.

13. The memory cell according to claim 12, wherein the conductive layer is made of metal germanium silicide.

14. The memory cell according to claim 11, wherein the metal gate layer is made of tantalum silicon nitride.

15. The memory cell according to claim 11, wherein the charge trapping layer is made of silicon nitride.

16. The memory cell according to claim 11, wherein the tunneling dielectric layer, the charge trapping layer, the inter-gate dielectric layer, and the metal gate layer form a gate structure.

17. The memory cell according to claim 16, further comprising a spacer on a sidewall of the gate structure.

18. The memory cell according to claim 16, further comprising a source/drain region in the substrate at each side of the gate structure.

19. The memory cell according to claim 18, further comprising a silicide layer, disposed on the metal gate layer and the source/drain region.

20. The memory cell according to claim 19, wherein the silicide layer is made of germanium-nickel silicide.

21. The memory cell according to claim 18, wherein the tunneling layer is made of aluminum-hafnium oxide.

22. The memory cell according to claim 21, wherein the metal gate layer is made of tantalum silicon nitride.

23. The memory cell according to claim 22, wherein the gate structure comprises a conductive layer, disposed on the metal gate layer, and the conductive layer is made of metal germanium silicide.

24. The memory cell according to claim 22, further comprising a silicide layer, disposed on the metal gate layer and the source/drain region.
